(19) United States
(12) Patent Application Publication
(10) Pub. No.: US 2007/0158052 A1
(43) Pub. Date: Jul. 12, 2007

(54) HEAT-DISSIPATING DEVICE AND METHOD FOR MANUFACTURING SAME

(75) Inventor: MONG-TUNG LIN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,813

(22) Filed: Oct. 3, 2006

(30) Foreign Application Priority Data
Jan. 10, 2006 (CN) 200610032901.4

(51) Int. Cl. H05K 7/20

(52) U.S. Cl. 165/104.33; 165/80.3; 361/700

(57) ABSTRACT

A vacuum heat-dissipating device (300) includes a container (310), a top wall (320) coupled to the container, and working fluid sealed in the heat-dissipating device. The container includes a bottom wall (312) and a peripheral wall (314) perpendicular to the bottom wall. A catalyst layer (330) is disposed on an inner surface of the bottom wall. A plurality of CNTs (340) are formed on the catalyst layer.

### DESCRIPTION

1. Field of the Invention

The present invention relates to a heat-dissipating device and a method for manufacturing the heat-dissipating device.

2. Description of Related Art

Many heat-dissipating devices combine the concepts of heat spreaders and heat pipes. Like a heat pipe, the basic working principle of the heat-dissipating device relies on large energy exchange during phase change of working fluid. Due to density and temperature differences in the vapor phase and liquid phase, molecules in the vapor phase will be pushed toward the relatively cooler wall of the heat-dissipating device and be condensed there. Generally there are wick structures on inner surface of the wall, which will provide capillary effect for re-circulating the condensed fluid back to the relatively higher temperature wall of the heat-dissipating device.

The selection of the fluid depends on the applications. Water has been the most popular and reliable one in most applications. Recently, fluids containing nano-sized particles have received much attention due to the added effect from the nano-sized particles in heat dissipating potential. The high heat condyctivities of the added particles/substances can raise the ensemble heat conductivity of the system. For example, a system composed of carbon nanotube (CNT) water solution, CNT has a thermal conductivity of 6600 W/m-K (watts/meter-Kelvin), can has a enhanced thermal conductivities up to 60%.

Referring to FIG. 5, the heat-dissipating device is a substantially cube-shaped container 100. The container 100 includes a bottom wall 110 connecting with a thermal source 150 and configured (i.e., structured and arranged) for acting as a heat sink, and a top wall 120 configured for dissipating heat. A plurality of fins 180 are arranged on the outer surface of the top wall 120. After evacuating, a working fluid 140 is sealed in the container 100. The working fluid 140 contains nano-sized particles 142.

However, in such a heat-dissipating device, the performance of nano-sized particles is not efficiently utilized. The heat-dissipating efficiency of the heat-dissipating device cannot satisfy size restrictions found in modern electric equipment.

What is needed, therefore, is to provide an efficient heat-dissipating device, and a method for manufacturing the heat-dissipating device.

### SUMMARY OF THE INVENTION

A heat-dissipating device includes a container, a top wall coupled to the container, and a working fluid received in the container. The container includes a bottom wall, and a peripheral wall interconnecting the bottom wall and the top wall. A catalyst layer is deposited on an inner surface of the bottom wall. A wick structure is constructed on an inner surface of the peripheral wall. A plurality of CNTs extends from the catalyst layer.

A method for manufacturing a heat-dissipating device includes the steps of: providing a container comprising a bottom wall and a peripheral wall extending therefrom; forming a catalyst layer on an inner surface of the bottom wall; growing carbon nanotubes on the catalyst layer; attaching a top wall to the container thereby obtaining a sealed container; evacuating the container, and introducing a working fluid into the container.

### BRIEF DESCRIPTION OF THE DRAWINGS

Many aspects of the present heat-dissipating device and method can be better understood with reference to the following drawings. The components in the drawings are not necessarily drawn to scale, the emphasis instead being placed upon clearly illustrating the principles of the present heat-dissipating device and method. Moreover, in the drawings, like reference numerals designate corresponding parts throughout the several views.

FIG. 1 is a diagrammatic flow chart of a method for manufacturing a heat-dissipating device in accordance with an exemplary embodiment of the present invention;

FIGS. 2A to 2F illustrate successive stages of the method shown in FIG. 1;

FIG. 3 is a cross sectional schematic view of a heat-dissipating device in accordance with a preferred embodiment;

FIG. 4 is a cross sectional schematic view of a heat-dissipating device in accordance with another embodiment; and

FIG. 5 is a cross sectional schematic view of a typical heat-dissipating device.

### DETAILED DESCRIPTION OF THE INVENTION

Reference will now be made to the drawings to describe in detail the preferred embodiments of the heat-dissipating device and the method.

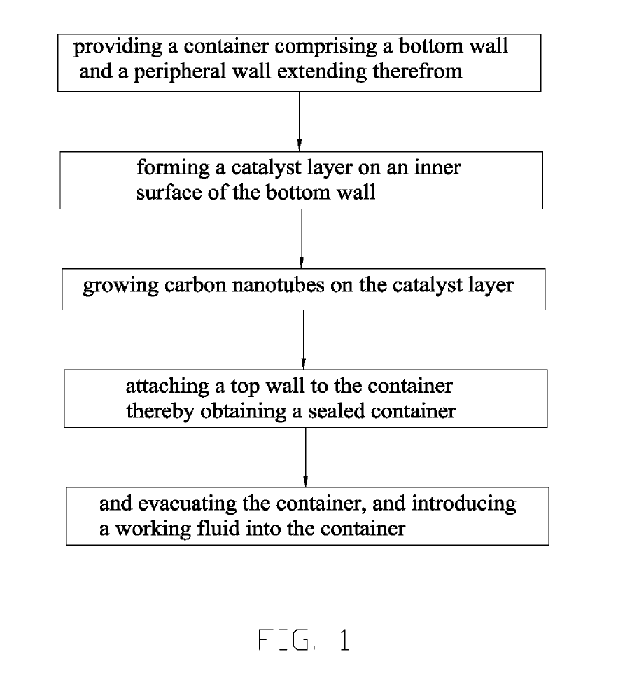

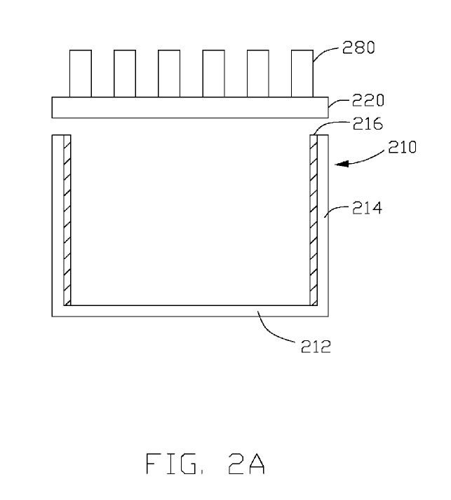

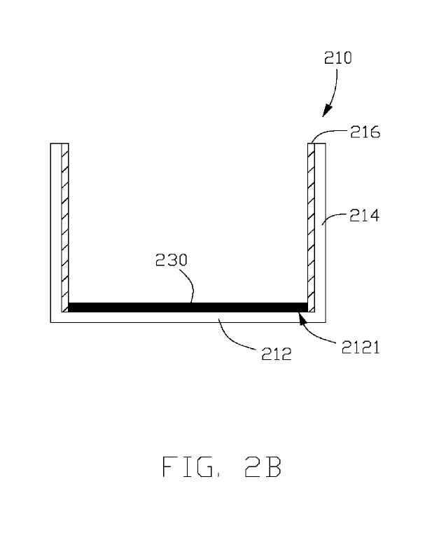

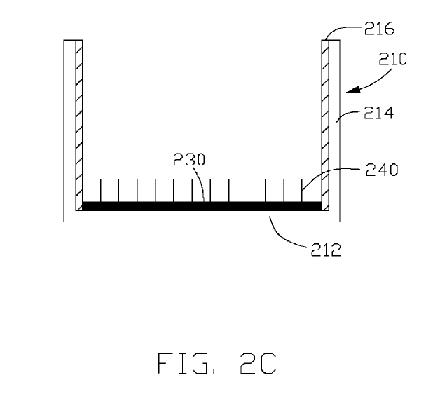

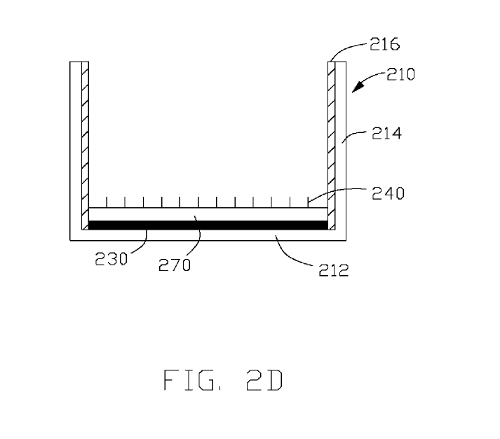

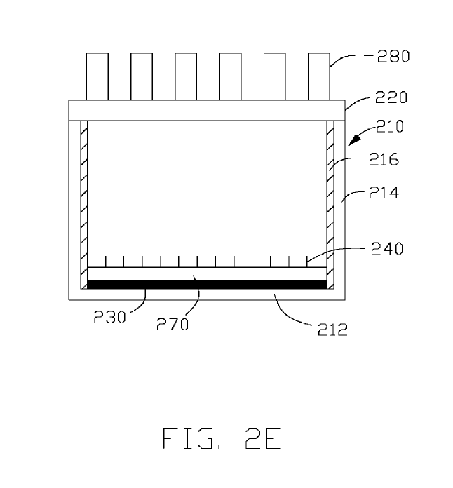

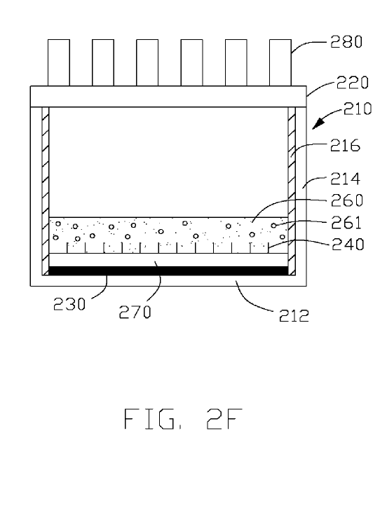

Referring to FIGS. 1 and 2A to 2F, a method for manufacturing a heat-dissipating device in accordance with an exemplary embodiment is shown. The method includes the steps of: providing a container 210, the container 210 includes a bottom wall 212 and a peripheral wall 214 extending therefrom; forming a catalyst layer 230 on an inner surface 2121 of the bottom wall 212; growing CNTs 240 on the catalyst layer 230; attaching a top wall 220 to the container 210 and then forming a sealed container 210 by sealing a top wall 220 to the container 210; evacuating the container 210 to form a vacuum, and introducing a working fluid 260 into the container.

In step (1), referring to FIG. 2A, the top wall 220 can be coupled to the peripheral wall 214. In the illustrated embodiment, the peripheral wall 214 is perpendicular to the bottom wall 212. The cross-section of the container 210 can be annular, arcuate, polygonal, etc. In the illustrated embodiment, cross-section of the container 210 is a rectangular shape. A material of the container 210 and the top wall 220 is selected from the group consisting of iron (Fe), cobalt (Co), nickel (Ni), copper (Cu), aluminum (Al), titanium (Ti) and any suitable alloy thereof. A plurality of fins 280 is arranged on an outer surface of the top wall 220 to dissipate heat more efficiently. Wick structures 216 are disposed on an inner surface of the peripheral wall 214. The wick structures 216 can be groove type, web type and/or sintered type.

In step (2), referring to FIG. 2B, the catalytic layer 230 is formed on the inner surface 2121 of the bottom wall 212 by a process selected from the group consisting of a thermal evaporation process, a sputtering process, and a thermal chemical vapor deposition process. The catalyst layer 230 is preferably made from a material selected from the group consisting of iron, copper, nickel, and any suitable combination thereof. The catalyst layer 230 can alternatively be made from other materials such as any suitable alloy of iron, copper, nickel, rare earth metals, and any suitable alloy of iron, copper, nickel and alkaline earth metals. In the preferred embodiment, copper is employed. A thickness of each of the catalyst layer 230 is advantageously in the range from about 1 nanometer to about 100 nanometers, and preferably from about 3 nanometers to about 30 nanometers.

In step (2), further includes a step of heating the catalyst layer 230 to obtain a desired catalyst particle size. Two alternative methods of heat treatment are described below by way of example:

(1)Heating the catalyst layer 230 over 30 minutes at 800 degrees Celsius with an inert gas such as helium gas (He), argon gas (Ar), or a mixture of the two; and then lowering the temperature to a temperature in the range from 550 degrees Celsius to 720 degrees Celsius.

### Rapid thermal annealing of the catalyst layer 230 at 800 degrees Celsius, and then lowering the temperature to a temperature in the range from 550 degrees Celsius to 720 degrees Celsius.

In step(3), referring to FIG. 2C, the CNTs 240 are then grown on the catalyst layer 230 via a chemical vapor deposition (CVD) process or a plasma enhanced chemical vapor deposition (PECVD) process. In the illustrated embodiment, the PECVD process is used. The temperature is maintained in the range from 500 degrees Celsius to 700 degrees Celsius. Typically, the heights of the CNTs 240 are in the range from about 10 milimeters (mm) to about 500 mm.

To secure the CNTs 240 on the copper bottom wall 212, an electro-deposition process is employed to provide extra copper filling 270 between individual CNTs 240, referring to FIG. 2D the height of the copper filling 270 is lower than that of CNTs 240, so that, the ends of CNTs 240 can be exposed outside.

In step(5), the working fluid 260 can be selected from the group consisting of pure water, ammonia, methane, acetone, and heptane. Preferably, the working fluid 260 has some nano-particles 261 added therein for improving heat conductivity thereof. The nano-particles 261 may be carbon nanotubes, carbon nanocapsules, nano-sized copper particles, and any suitable mixture thereof. The wick structure 216 of the peripheral wall 214 will allow the working fluid 260 to diffuse along different directions.

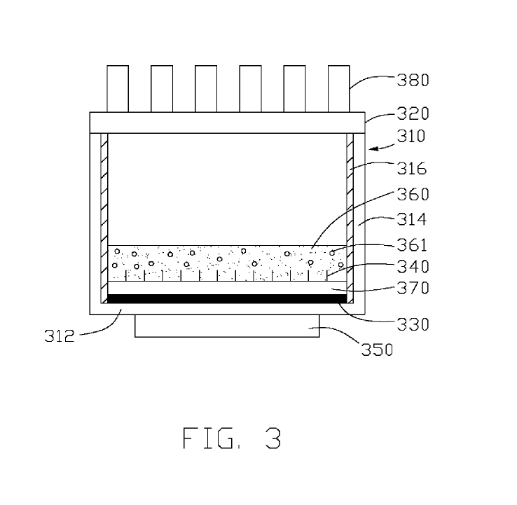

Referring to FIG. 3, in according with another embodiment, a vacuum heat-dissipating device 300 includes a container 310, a top wall 320 coupled to the container 310, and working fluid 360 sealed in the heat-dissipating device 300. The container 310 includes a bottom wall 312 and a peripheral wall 314. A catalyst layer 330 is disposed on an inner surface of the bottom wall 312. A plurality of CNTs 340 grown from the catalyst layer 330 is formed on the catalyst layer 330.

The cross-section of the container 310 can be annular, arcuate, polygonal, etc. In the illustrated embodiment, cross-section of the container 310 is rectangular shape. A material of the container 310 and the top wall 320 is selected from the group consisting of iron, copper, nickel, cobalt, aluminum, titanium, and any suitable alloy thereof. A plurality of fins 380 is arranged on one surface of the top wall 320 facing outside to improve irradiation efficiency. Wick structures 316 are disposed on an inner surface of the peripheral wall 314. The wick structures 316 can be groove type, web type and/or sintered type.

The catalyst layer 330 is preferably made from material selected from the group consisting of iron, copper, nickel, and any suitable alloy thereof. The catalyst layer 330 can alternatively be made from other materials such as any suitable alloy of iron, copper, nickel and a rare earth metals, and any suitable alloy of iron, copper, nickel and alkaline earth metal. In the preferred embodiment, copper is employed. A thickness of the catalyst layer 330 is advantageously in the range from about 1 nanometer to about 100 nanometers, and preferably from about 3 nanometers to about 30 nanometers.

The CNTs 340 are grown on the catalyst layer 330 via a CVD process or a PECVD process. The heights of the CNTs 340 are in the range from about 10 mm to about 500 mm.

To further secure the CNTs 340 on the copper bottom wall 312, an electro-deposition technique is employed to provide extra copper filling 370 among individual CNTs 340. The height of the copper filling 370 is lower than that of CNTs 340, so the ends of CNTs 340 can extrude above the copper layer.

The working fluid 360 can be selected from the group consisting of pure water, ammonia, methane, acetone, and heptane. Preferably, the working fluid 360 has some nano-particles 361 added therein for improving heat conductivity thereof. The nano-particles 361 may be carbon nanotubes, carbon nanocapsules, nano-sized copper particles, and any suitable mixture thereof.

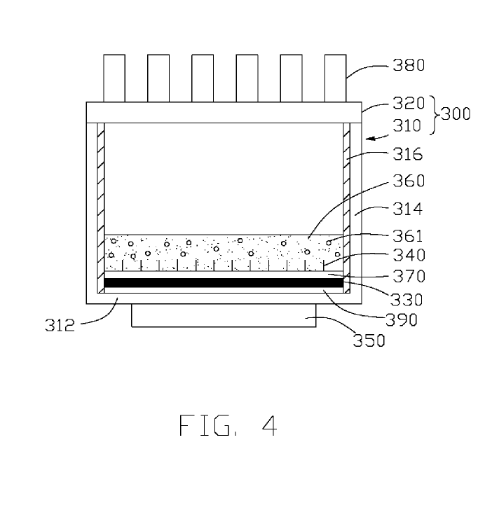

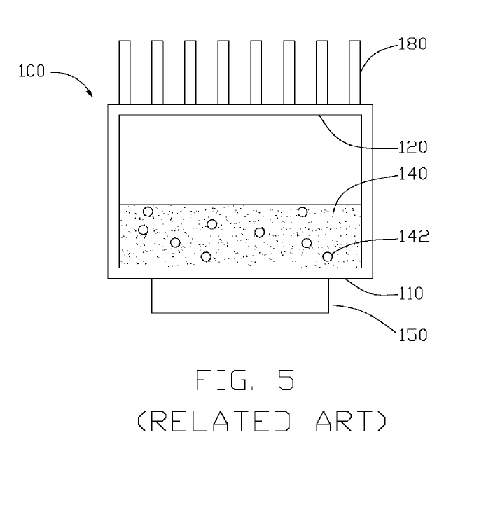

Referring to FIG. 4, the vacuum heat-dissipating device 300 further includes a buffer layer 390 sandwiched between the catalyst layer 330 and the bottom wall 312. The buffer layer 390 is configured for preventing the catalyst layer 330 diffusing to the bottom wall 312. A material of the buffer layer 390 is selected from the group consisting of titanium, titanium oxide, molybdenum (Mo), and any combination thereof.

In operation, a thermal source 350 emits heat, which is then transferred to the bottom wall 312, causing the working fluid 360 to evaporate and move toward the top wall 320, where the vapor will be cooled and condensed. The condensed fluid is then transferred back to the bottom via capillary effect through the wick structures 316. The container 310 and the top wall 320 co-operatively form a vacuum container 300, so that evaporation of the working fluid can occur at lower temperatures than would occur at atmospheric pressure.

While the present invention has been described as having preferred or exemplary embodiments, the embodiments can be further modified within the spirit and scope of this disclosure. This application is therefore intended to top wall any variations, uses, or adaptations of the embodiments using the general principles of the invention as claimed. Further, this application is intended to top wall such departures from the present disclosure as come within known or customary practice in the art to which the invention pertains and which fall within the limits of the appended claims or equivalents thereof.

What is claimed is:

1. A heat-dissipating device, comprising:
a container comprising
a bottom wall, a top wall and a peripheral wall interconnecting the bottom wall and the top wall;
a working fluid received in the container;
a wick structure disposed on an inner surface of the peripheral wall;
a catalyst layer disposed on an inner surface of the bottom wall; and
a plurality of carbon nanotubes extending from the catalyst layer.

2. The heat-dissipating device as described in claim 1, wherein the container is a vacuum container.

3. The heat-dissipating device as described in claim 1, wherein the container is comprised of a material selected from the group consisting of iron, cobalt, nickel, copper, aluminum, titanium, and any alloy thereof.

4. The heat-dissipating device as described in claim 1, further comprising a plurality of fins arranged on an outer surface of the top wall of the container.

5. The heat-dissipating device as described in claim 1, wherein the catalyst layer is comprised of a material selected from the group consisting of iron, cobalt, nickel, and any combination thereof.

6. The heat-dissipating device as described in claim 1, wherein the catalyst layer is comprised of alloy of iron, cobalt, nickel and an alkaline earth metal.

7. The heat-dissipating device as described in claim 1, wherein the catalyst layer is comprised of iron-copper-nickel alloy and a rare earth metal.

8. The heat-dissipating device as described in claim 1, wherein the catalyst layer is comprised of copper.

9. The heat-dissipating device as described in claim 1, further comprising a copper layer formed on the bottom wall, wherein the carbon nanotubes are embedded in the copper layer.

10. The heat-dissipating device as described in claim 1, wherein the working fluid is selected from the group consisting of water, ammonia, methane, acetone, and heptane.

11. The heat-dissipating device as described in claim 9, wherein the working fluid further comprises nano-particles, the nano-particles are selected from the group consisting of carbon nanotubes, carbon nanocapsules, nano-sized copper particles, and any mixture thereof.

12. The heat-dissipating device as described in claim 1, further comprising a buffer layer sandwiched between the catalyst layer and the bottom wall, the buffer layer being configured for preventing the catalyst layer from diffusing into the bottom wall.

13. The heat-dissipating device as described in claim 11, wherein the buffer layer is comprised of a material selected from the group consisting of titanium, titanium oxide, molybdenum, and any combination thereof.

14. A method for manufacturing a heat-dissipating device, the method comprising the steps of:
providing a container comprising a bottom wall and a peripheral wall extending therefrom;
forming a catalyst layer on an inner surface of the bottom wall;
growing carbon nanotubes on the catalyst layer;
attaching a top wall to the container thereby obtaining a sealed container; and
evacuating the container, and
introducing a working fluid into the container.

15. The method as described in claim 14, wherein the catalyst layer is formed on the inner surface of the bottom wall using a process selected from the group consisting of a thermal evaporation process, a sputtering process, or a thermal chemical vapor deposition process.

16. The method as described in claim 14, further comprising a step of heating the catalyst layer so as to obtain a desired catalyst particle size prior to growing the carbon nanotubes.

17. The method as described in claim 14, wherein the carbon nanotubes are grown on the catalyst layer using a chemical vapor deposition process or a plasma enhanced chemical vapor deposition process.

18. The method as described in claim 14, prior to evacuating step further comprising a step of forming a copper layer on the bottom wall thereby lower portions of the carbon nanotubes being embedded in the copper layer using an electro-deposition process.
